(19) United States
(12) Patent Application Publication
(10) Pub. No.: US 2023/0328900 A1
(43) Pub. Date: Oct. 12, 2023

(54) CIRCUIT BOARD AND CIRCUIT BOARD MODULE WITH DOCKING STRUCTURE AND MANUFACTURE METHOD OF THE CIRCUIT BOARD

(71) Applicant: UNIMICRON TECHNOLOGY CORP., Taoyuan City (TW)

(72) Inventor: Shih-Lian Cheng, New Taipei City (TW)

(21) Appl. No.: 17/741,499

(22) Filed: May 11, 2022

(30) Foreign Application Priority Data
Apr. 8, 2022 (TW) 111113495

(51) Int. Cl. H05K 3/46; H05K 3/00; H05K 3/24; H05K 3/04; H05K 1/02

(52) U.S. Cl. CPC H05K 3/4697; H05K 3/0097; H05K 3/0094; H05K 3/0044; H05K 3/241; H05K 3/04; H05K 1/0298; H05K 2201/09127; H05K 2203/025

(57) ABSTRACT

In the manufacture method of the present invention, an inner circuit structure is prepared, and a docking pad is formed on the first surface of the inner circuit structure. A release film is mounted on the first surface to cover the docking pad before mounting a build-up circuit structure upon the first surface. The release film and part of the build-up circuit structure above it are removed. The docking pad is therefore exposed and a docking opening is formed in the build-up circuit structure. The docking opening is for mounting a circuit board to be docked to form a circuit board module of the present invention.

### CROSS REFERENCE TO RELATED APPLICATION

The present application claims priority to Taiwan application No. 111113495, filed on Apr. 8, 2022, the content of which is hereby incorporated by reference in its entirety.

### BACKGROUND OF THE INVENTION

### 1. Field of the Invention

The present invention relates to a circuit board, a circuit board module, and a manufacture method of the circuit board, in particular to a circuit board and a circuit board module with a docking structure and a manufacture method of the circuit board with the docking structure.

### 2. Description of the Related Art

In the procedures of docking two circuit boards of the same size to each other, the two circuit boards can be aligned with each other by an edge aligning method. The edge aligning method is a mature technique and can be performed at low cost and with high precision. However, for two circuit boards of different sizes, they cannot be aligned with each other by the edge aligning method. Another common method for this situation is applying a copper paste embedding technique of a Transient Liquid Phase Sintering process.

A conventional process of docking a first circuit board and a second circuit board is described as follows.

With reference to FIG. 5A and FIG. 5B, firstly, a fixture 61 for pressing and a resin blocking layer 62 are prepared. As shown in FIG. 5A, the fixture 61 has an accommodation opening 610 in a shape and a size that correspond to a shape and a size of the second circuit board. As shown in FIG. 5B, the resin blocking layer 62 has an alignment opening 620 and multiple alignment holes 621. A shape and a size of the alignment opening 620 also correspond to the shape and the size of the second circuit board.

With reference to FIG. 6A, the first circuit board 51 includes a composite circuit structure 511, a solder mask layer 512, and at least one surface bonding pad 513. The surface bonding pad 513 is exposed at a surface of the solder mask layer 512. With reference to FIG. 6B, the resin blocking layer 62 is aligned with the first circuit board 51, and an alignment rivet 63 is mounted through the alignment holes 621 and penetrates the first circuit board 51. With reference to FIG. 6C, the second circuit board 52 is mounted in the alignment opening 620 of the resin blocking layer 62. The surface of the second circuit board 52 that faces the first circuit board 51 has an adhesive layer 521 and at least one copper paste bump 522 exposed from the adhesive layer 521. The copper paste bump 522 directly contacts the surface bonding pad 513 of the first circuit board 51. The fixture 61 as shown in FIG. 5A is than mounted on the resin blocking layer 62, such that the second circuit board 52 is placed in the accommodation opening 610 of the fixture 61. Pressuring and sintering processes are then performed to the first circuit board 51 and the second circuit board 52, such that the adhesive layer 521 of the second circuit board 52 is bonded to the surface of the soldering mask 512 of the first circuit board 51, and the copper paste bump 522 of the second circuit board 52 is bonded to the surface bonding pad 513 of the first circuit board 51. With reference to FIG. 6D, the fixture 61, the resin blocking layer 62, and the alignment rivet 63 are removed. Then, a circuit board cutting process is performed to obtain a unit of a docked circuit board module.

The conventional process as described above has defects. Firstly, to avoid that the adhesive layer 521 overflows to the non-bonding area of the first circuit board 51 and covers other bonding pads, the resin blocking layer 62 is necessary to be made. The material of the resin blocking layer 62 must be tightly bonded to the surface of the first circuit board 51, and residue of the resin blocking layer 62 is hardly prevented after the sintering process and removing the resin blocking layer 62. The residue of the resin blocking layer 62 cannot be detected easily, and may cause a drop of yield rate. Secondly, the resin blocking layer 62 is expensive and cannot be reused, causing a rise in manufacture cost. Thirdly, during the pressuring and sintering process, the glass transition temperatures (Tg) of the adhesive layer 521 and the copper paste bond 522 of the second circuit board 52 must match the Tg of the resin blocking layer 62. Therefore, the selection for the materials of the adhesive layer 521 and the copper paste bump 522 is limited.

### SUMMARY OF THE INVENTION

An objective of the present invention is to provide a circuit board and a circuit board module with a docking structure that overcome the defects of the conventional process, including the resin residue, the limited selection for the materials, and the rise in manufacture cost.

To achieve the foregoing objective, the present invention provides a circuit board with a docking structure including an inner circuit structure and a first build-up circuit structure. The inner circuit structure has a first surface and a docking pad on the first surface. The first build-up circuit structure is mounted on the first surface of the inner circuit structure, and has a docking opening, wherein the docking pad is exposed in the docking opening.

In an embodiment, a spatial shape of the docking opening of the first build-up circuit structure fits a shape of a circuit board to be docked.

In an embodiment, the first build-up circuit structure includes a first dielectric layer and a first circuit layer. The first dielectric layer is mounted on the first surface of the inner circuit structure, and has the docking opening. The first circuit layer is mounted on the first dielectric layer, and has a circuit pattern that does not cover the docking opening.

In an embodiment, the circuit board further includes a second build-up circuit structure and a conductive via. The second build-up circuit structure is mounted on a second surface of the inner circuit structure, and includes a second circuit structure, wherein the second surface of the inner circuit structure is opposite to the first surface of the inner circuit structure. The conducting via includes a through hole, a conductive layer, and a hole filler. The through hole is formed through the first build-up circuit structure, the inner circuit structure, and the second build-up circuit structure. The conductive layer is mounted on an inner wall of the through hole, and is electrically connected to the first circuit layer of the first build-up circuit structure and the second circuit layer of the second build-up circuit structure. The hole filler is filled in the through hole.

The present invention also provides a circuit board module with a docking structure including a first circuit board and a second circuit board. The first circuit board includes an inner circuit structure and a first build-in circuit structure. The inner circuit structure has a first surface and a docking pad on the first surface. The first build-up circuit structure is mounted on the first surface of the inner circuit structure, and has a docking opening, wherein the docking pad is exposed in the docking opening. The second circuit board has a docking surface and includes an adhesive layer and a docking bump. The adhesive layer is mounted on the docking surface. The docking bump is mounted on the docking surface and protrudes from the adhesive layer. The second circuit board is mounted in the docking opening of the first circuit board. The docking surface of the second circuit board faces the first surface in the docking opening. The docking bump is connected to the docking pad of the inner circuit structure. The adhesive layer adheres to the first surface.

In an embodiment, a spatial shape of the docking opening of the first build-up circuit structure fits a shape of the second circuit board.

In an embodiment, the first build-up circuit structure of the first circuit board includes a first dielectric layer and a first circuit layer. The first dielectric later is mounted on the first surface of the inner circuit structure, and has the docking opening. The first circuit layer is mounted on the first dielectric layer, and has a circuit pattern that does not cover the docking opening.

In an embodiment, the first circuit board includes a second build-up circuit structure and a conducting via. The second build-up circuit structure is mounted on a second surface of the inner circuit structure, and includes a second circuit structure, wherein the second surface of the inner circuit structure is opposite to the first surface of the inner circuit structure. The conducting via includes: a through hole, a conductive layer, and a hole filler. The through hole is formed through the first build-up circuit structure, the inner circuit structure, and the second build-up circuit structure. The conductive layer is mounted on an inner wall of the through hole, and is electrically connected to the first circuit layer of the first build-up circuit structure and the second circuit layer of the second build-up circuit structure. The hole filler is filled in the through hole.

The present invention also provides a manufacture method of a circuit board with a docking structure, including steps of:
preparing an inner circuit structure having a first surface and a docking pad on the first surface;
mounting a release film on the first surface, wherein the release film covers the docking pad;
mounting a first build-up circuit structure on the first surface of the inner circuit structure;
forming a groove along an edge of the release film on a surface of the first build-up circuit structure, wherein the groove is formed through the first build-up circuit structure, such that a part of the first build-up circuit structure on top of the release film is separated from the rest of the first build-up circuit structure; and
removing the release film from the first surface of the inner circuit structure to remove the part of the first build-up circuit structure on top of the release film and expose the docking pad, to form a docking opening in the first build-up circuit structure.

In an embodiment, a spatial shape of the docking opening of the first build-up circuit structure fits a shape of a circuit board to be docked.

In an embodiment, the manufacture method further includes the steps of: mounting a second build-up circuit structure on a second surface of the inner circuit structure; wherein the second surface of the inner circuit structure is opposite to the first surface of the inner circuit structure; wherein the step of mounting the first build-up circuit structure or mounting the second build-up circuit structure further includes sub-steps of:
mounting a first dielectric layer covering the first surface of the inner circuit structure, and mounting a second dielectric layer covering the second surface of the inner circuit structure; and
mounting a first circuit layer on a surface of the first dielectric layer, and mounting a second circuit layer on a surface of the second dielectric layer; wherein the first circuit layer has a circuit pattern that does not cover a region above the release film.

In an embodiment, after mounting the first dielectric layer and the second dielectric layer, the manufacture method further includes sub-steps of:
performing a drilling process to form a through hole through the inner circuit structure, the first dielectric layer, and the second dielectric layer;
performing an electroplating process to form a conductive layer in the through hole and on a surface of the first dielectric layer and a surface of the second dielectric layer, and then filling the through hole with a hole filler, to form a conducting via; wherein the first circuit layer is mounted on the conductive layer upon the first dielectric layer, and the second circuit layer is mounted on the conductive layer upon the second dielectric layer.

In an embodiment, after filling the through hole with the hole filler, the manufacture method further includes steps of:
scrubbing the surface of the first dielectric layer and the surface of the second dielectric layer to remove redundant hole filler and reducing a thickness of the conductive layer on the first dielectric layer and the second dielectric layer;
mounting circuit metal layers on the conductive layer on the first dielectric layer and the second dielectric layer respectively; and
patterning the circuit metal layers on the first dielectric layer and the second dielectric layer to form the first circuit layer and the second circuit layer.

The circuit board of the present invention directly exposes the docking pad on the first surface of the inner circuit structure by forming the docking opening in the first build-up circuit structure, such that the circuit board to be docked can be mounted directly in the docking opening to be bonded with the first surface of the inner circuit structure and connected to the docking pad. The docking opening of the first build-up circuit structure has an effect of accommodating an overflow from the adhesive layer. When the circuit board to be docked is mounted and pressed in the docking opening and adhered to the first surface of the inner circuit structure, the position of the adhesive layer on the surface of the circuit board to be docked will be limited within the docking opening. Therefore, the overflow from the adhesive layer to the surface of the first build-up circuit structure is prevented. The docking process for the circuit board of the present invention omits the use of a resin blocking layer as mentioned in the prior art, such that the present invention achieves the purposes of preventing resin overflowing, avoiding residue from the resin blocking layer, avoiding the limited selection for materials, and reducing the manufacture cost.

The circuit board module with a docking structure of the present invention includes the circuit board with the docking structure as described above and the circuit board to be docked. The circuit board to be docked is mounted in the docking opening of the first build-up circuit structure, and the adhesive layer is bonded to the first surface of the inner circuit structure within the docking opening. Therefore, the adhesive layer can hardly overflow from the docking opening. The docking opening of the first build-up circuit structure provides the function replacing the resin blocking layer as mentioned in the prior art, and achieves the purposes of preventing resin overflowing, avoiding residue from the resin blocking layer, avoiding the limited selection for materials, and reducing the manufacture cost.

In the circuit board manufacture method of the present invention, in order to form the docking opening in the first build-up circuit structure and to retain the docking pad on the first surface of the inner circuit structure in a bottom of the docking opening, the manufacture method of the present invention is to mount the release film on the docking pad on the first surface of the inner circuit structure to cover the docking pad at first, and then proceeds to a build-up process for mounting the first build-up circuit structure. After the first build-up circuit structure is mounted, the present invention is just to form a groove along the edge of the release film to separate a part of the first build-up circuit structure that is on top of the release film, and therefore such part of the first build-up circuit structure can be removed directly to form the docking opening in the first build-up circuit structure and expose the docking pad. The release film protects the docking pad of the inner circuit structure in the build-up process, and causes the part of the first build-up circuit structure to be easily removable from the first surface and the docking pad of the inner circuit structure.

Other objectives, advantages and novel features of the present invention will become more apparent from the following detailed description when taken in conjunction with the accompanying drawings.

### BRIEF DESCRIPTION OF THE DRAWINGS

FIG. 1 is a cross sectional view of a circuit board with a docking structure of the present invention.

FIG. 2 is a cross sectional view of a circuit board to be docked in the circuit board module with a docking structure of the present invention.

FIG. 3A-FIG. 3K are cross sectional views of a manufacture method of the circuit board with a docking structure.

FIG. 4A-FIG. 4C are cross sectional views of a docking process of the circuit board module with a docking structure.

FIG. 5A is a sectional view of a fixture for circuit boards bonding of a conventional art.

FIG. 5B is sectional view of a resin blocking layer for circuit boards bonding of a conventional art.

FIG. 6A-FIG. 6D are cross sectional views of a bonding process of the circuit boards of a conventional art.

### DETAILED DESCRIPTION OF THE INVENTION

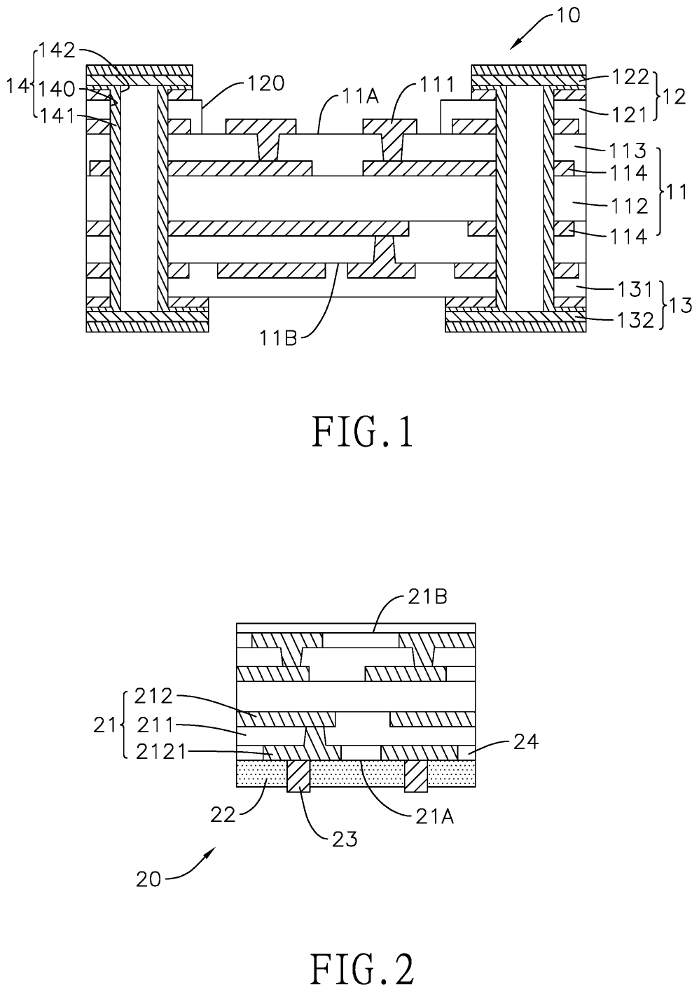

With reference to FIG. 1 and FIG. 2, a circuit board with a docking structure (hereinafter referred to as a first circuit board 10) of the present invention includes an inner circuit structure 11 and a first build-up circuit structure 12. The first circuit board 10 is designed to be connected to a circuit board to be docked (hereinafter referred to as a second circuit board 20). The inner circuit structure 11 has a first surface 11A and a second surface 11B that is opposite to the first surface 11A. At least one docking pad 111 is mounted on the first surface 11A. The docking pad 111 is connected t to at least one docking bump 23 of the second circuit board 20 when the second circuit board 20 is docked with the first circuit board 10. The first build-up circuit structure 12 is mounted on the first surface 11A of the inner circuit structure 11 and has a docking opening 120. The docking pad 111 is exposed in the docking opening 120.

The inner circuit structure 11 may include a core layer 112 and at least one circuit layer 114 mounted on surface(s) of the core layer 112. The inner circuit structure 11 may further include at least one dielectric layer 113 and at least one circuit layer 114 on the at least one dielectric layer 113. The embodiment in FIG. 1 shows an inner circuit structure 11 with two dielectric layers 113 and four circuit layers 114 as an example, but the present invention is not limited to such configuration. The first surface 11A and the second surface 11B are the surfaces where the outer circuit layer 114 is mounted. The docking pads 111 are circuit patterns that are formed with a formation process of the outer circuit layer 114 on the first surface 11A at the same time.

The first build-up circuit structure 12 may include at least one first dielectric layer 121 and at least one first circuit layer 122. The embodiment in FIG. 1 shows a first build-up circuit structure 12 with one dielectric layer 121 and one first circuit layer 122, but the present invention is not limited to such configuration. The first dielectric layer 121 is mounted on the first surface 11A of the inner circuit structure 11, and has the docking opening 120. The first circuit layer 122 is mounted on the first dielectric layer 121 and has a circuit pattern that does not cover the docking opening 120. Namely, the first circuit layer 122 and the docking opening 120 are formed on different positions.

In an embodiment, the spatial shape of the docking opening 120 fits a shape of the second circuit board 20. Namely, the docking opening 120 is formed according to a length, a width, or a shape of the second circuit board 20. Therefore, when the second circuit board 20 is to be docked with the first circuit board 10, the position of the second circuit board 20 will be limited within the docking opening 120 and fixed at a target position, such that the docking opening 120 provides an auto-aligning effect.

In an embodiment, the first circuit board 10 includes a second build-up circuit structure 13. The second build-up circuit structure 13 is mounted on the second surface 11B of the inner circuit structure 11, and includes at least one dielectric layer 131 and at least one second circuit layer 132. The first circuit board 10 has a conducting via 14 that is formed through the first build-up circuit structure 12, the inner circuit structure 11, and the second build-up circuit structure 13. The conducting via 14 includes a through hole 140, a conductive layer 141 mounted on an inner wall of the through hole 140, and hole filler 142 filled in the through hole 140. The first circuit layer 122 of the first build-up circuit structure 12 and the second circuit layer 132 of the second build-up circuit structure 13 are electrically connected to each other through the conductive layer 141. Preferably, the first circuit layer 122 of the first build-up circuit structure 12, the circuit layer of the inner circuit structure 11, and the second circuit layer 132 of the second build-up circuit structure 13 are selectively electrically connected to one another through the conducting via 14.

The circuit board module of the present invention includes the first circuit board 10, and further includes the second circuit board 20.

With reference to FIG. 2, in an embodiment, a composite circuit structure 21 of the second circuit board 20 includes at least one dielectric layer 211 and at least one circuit layer 212, and has a docking surface 21A. An adhesive layer 22 and at least one docking bump 23 are mounted on the docking surface 21A. The docking bump 23 protrudes from the surface of the adhesive layer 22 for bonding and being electrically connected to the docking pad 111 of the first circuit board 10. The material of the docking bump 23 may be copper paste. To be more specific, the second circuit board 20 further includes a solder mask layer 24. The solder mask layer 24 covers the circuit layer 212 at the docking surface 21A of the composite circuit structure 21. Besides, a surface bonding pad 2121 of the at least one circuit layer 212 located on the docking surface 21A is exposed from the solder mask layer 24. The adhesive layer 22 is mounted on and covers the circuit layer 212 at the docking surface 21A and the solder mask layer 24, and has at least one blind hole 221 that is formed according to the position of the surface bonding pad 2121. The docking bump 23 is mounted in the blind hole 221 and is electrically connected to the circuit layer 212 through the surface bonding pads 2121 exposed at the bottom of the blind hole 221.

The manufacture method of the circuit board with a docking structure of the present invention is described below.

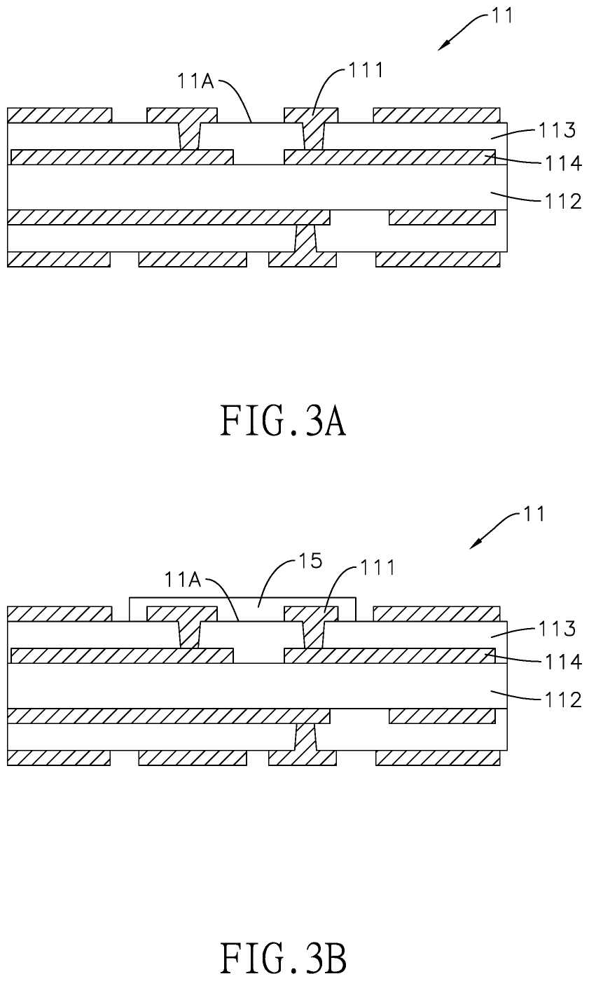

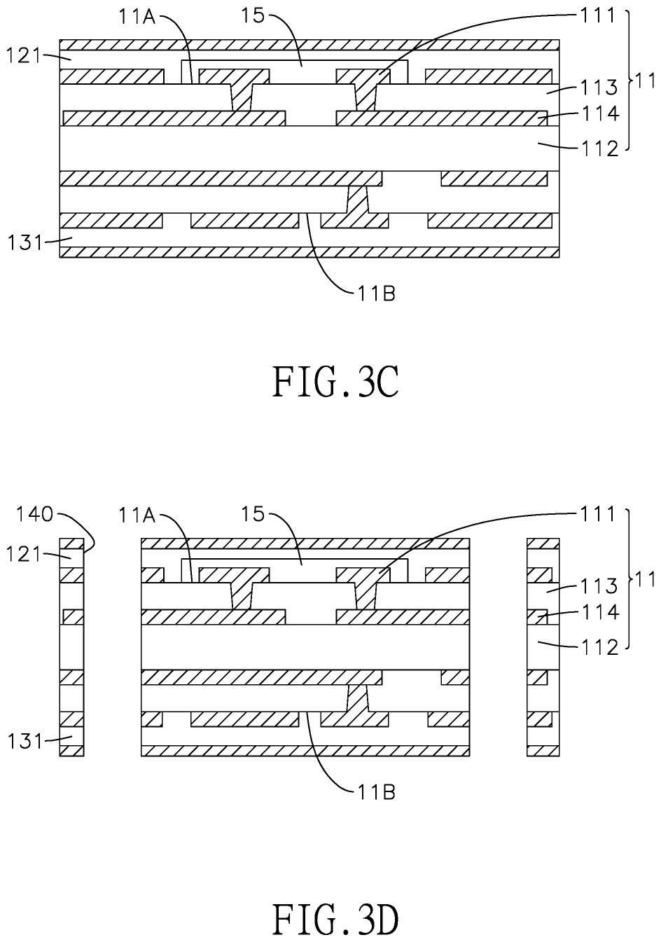

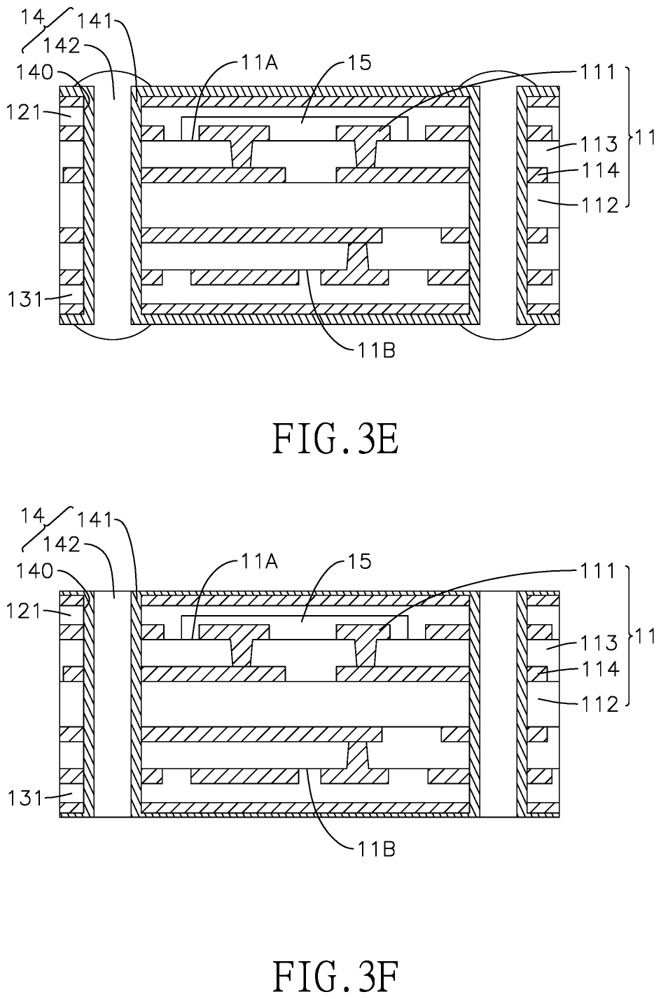

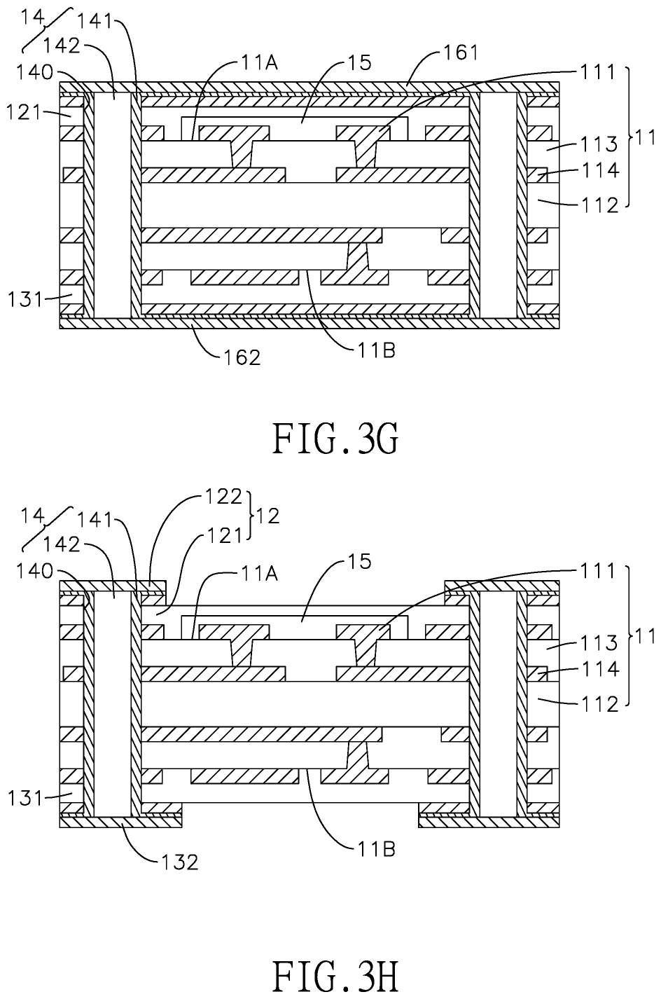

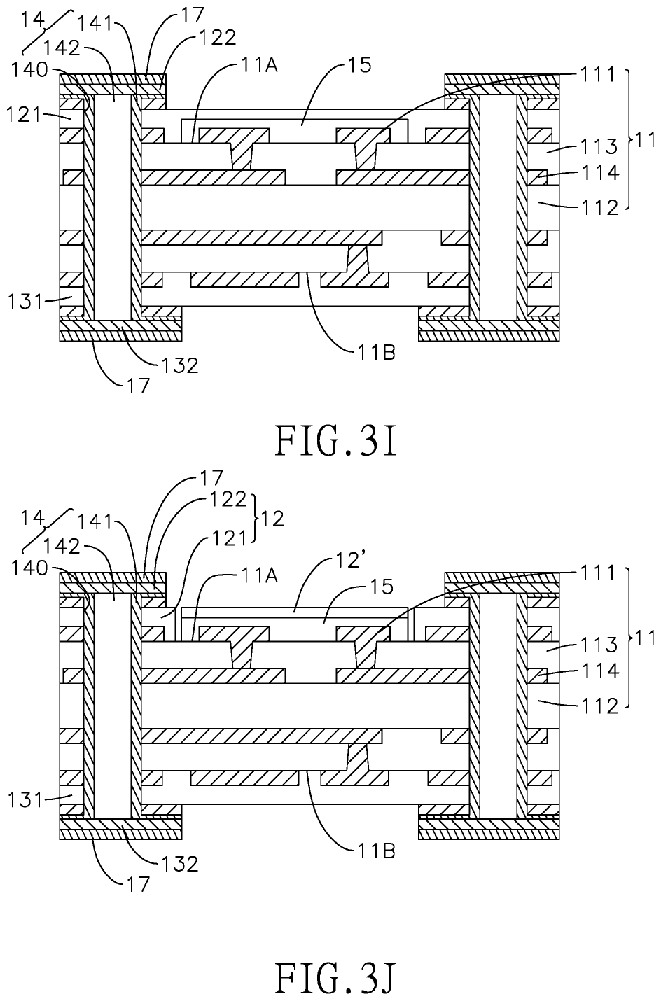

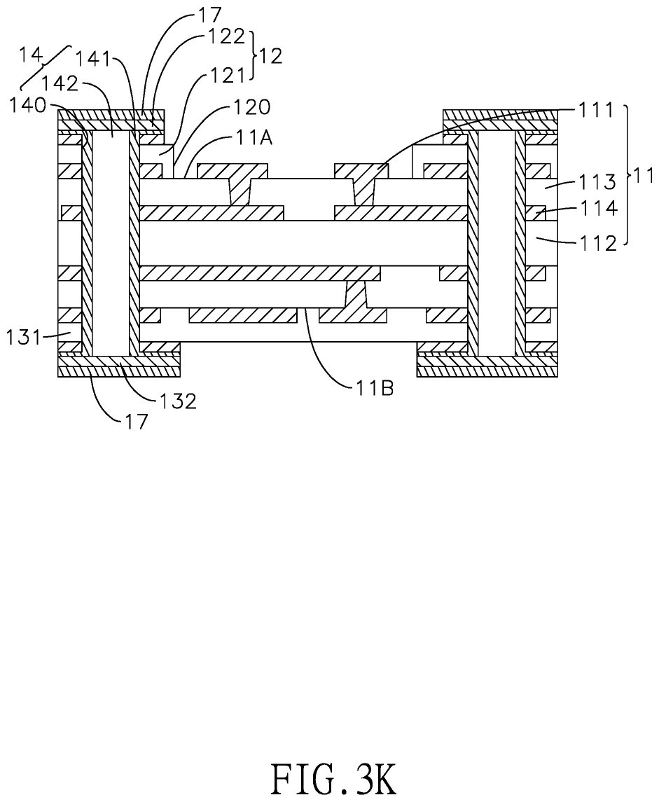

With reference to FIG. 3A, this step is to prepare the inner circuit structure 11. The inner circuit structure 11 has the first surface 11A and a docking pad 111 on the first surface 11A.

With reference to FIG. 3B, this step is to mount the release film 15 on the first surface 11A of the inner circuit structure 11. The release film 15 covers the docking pad 111.

The first build-up circuit structure 12 is then mounted on the first surface 11A. While a build-up process is performed on the first surface 11A to form the first build-up circuit structure 12, another build-up process can be performed simultaneously to mount the second build-up circuit structure 13 on the second surface 11B.

To be more specific, the steps of mounting the first build-up circuit structure 12 and the second build-up circuit structure 13 on the first surface 11A and the second surface 11B may include the following sub-steps.

With reference to FIG. 3C, this sub-step is to mount the first dielectric layer 121 on the first surface 11A to cover the first surface 11A, and to mount the second dielectric layer 131 on the second surface 11B to cover the second surface 11B.

With reference to FIG. 3D, this sub-step is to perform a drilling process to form a through hole 140 that is formed through the inner circuit structure 11, the first dielectric layer 121, and the second dielectric layer 131.

With reference to FIG. 3E, this sub-step is to perform an electroplating process to form a conductive layer 141 in the through hole 140 and, on the surface of the first dielectric layer 121, and on the surface of the second dielectric layer 131, and then to fill the through hole 140 with the hole filler 142, to form the conducting via 14.

With reference to FIG. 3F, this sub-step is to scrub the surface of the first dielectric layer 121 and the surface of the second dielectric layer 131 to remove redundant hole filler 142, and to reduce the thickness of the conductive layer 141 on the first dielectric layer 121 and the second dielectric layer 131.

With reference to FIG. 3G, this sub-step is to mount a circuit metal layer 161 on the conductive layer 141 on the first dielectric layer 121, and to mount a circuit metal layer 162 on the conductive layer 141 on the first dielectric layer 131.

With reference to FIG. 3H, this sub-step is to pattern the circuit metal layers 161, 162 on the first dielectric layer 121 and the second dielectric layer 131 to form the first circuit layer 122 and the second circuit layer 132. In some embodiments, the patterning of the circuit metal layers 161, 162 is done by a photolithography process.

With reference to FIG. 3I, preferably, after finishing the first build-up circuit structure 12 and the second build-up circuit structure 13, a surface process for mounting a protective layer 17 on the surface of the first circuit layer 122 and the second circuit layer 132 may be performed. The material of the protective layer 17 may be electroless nickel immersion gold layer (ENIG) or electroplated gold.

With reference to FIG. 3J, after finishing the first build-up circuit structure 12 and the second build-up circuit structure 13, a groove is formed on the surface of the first build-up circuit structure 12 and along the edge of the release film 15, and through the first build-up circuit structure 12 to the first surface 11A of the inner circuit structure 11. A part of the first build-up circuit structure 12 that is on top of the release film 15 is therefore separated from the rest of the first build-up circuit structure 12. The formation process of the groove may be performed by milling or laser drilling.

Since the position of the release film 15 on the first surface 11A of the inner circuit structure 11 and a thickness of the first build-up circuit structure 12 are predetermined and known, the formation process of the groove by milling or laser drilling may be automatically controlled by computer program, so that the computer program can form the groove precisely to the depth as the first surface 11A of the inner circuit structure 11 and along the edge of the release film 15. The degree of precision of the laser drilling may come to 20 μm as an example. Therefore, the shape and the size of the docking opening 120 may precisely correspond to the shape and the size of the second circuit board 20. As a result, when the second circuit board 20 is placed on the first circuit board 10 for preparation of docking, the second circuit board 20 may fall into the docking opening 120 and be automatically aligned and fixed to the predetermined docking area.

With, reference to FIG. 3K, this step is to remove the release film 15 from the first surface 11A of the inner circuit structure 11 to remove the part of the first build-up circuit structure 12 that is on top of the release film 15 with the release film 15, and to form the docking opening 120. The first circuit board 10 is completed in this step. The removing of the release film 15 may be, but is not limited to be operated by hand by an operator.

The docking process of the first circuit board 10 and the second circuit board 20 is described below.

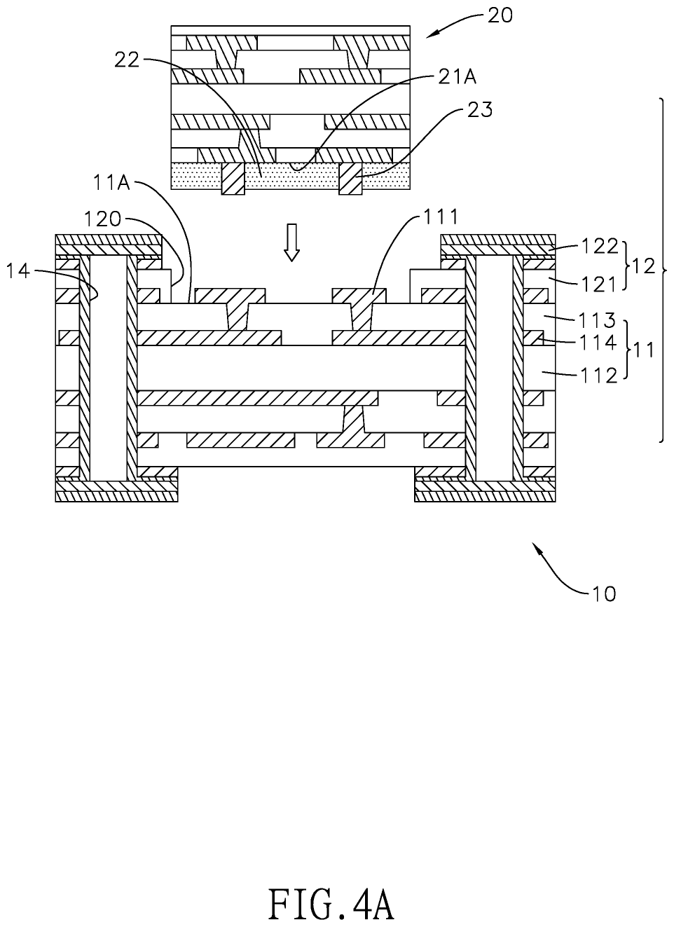

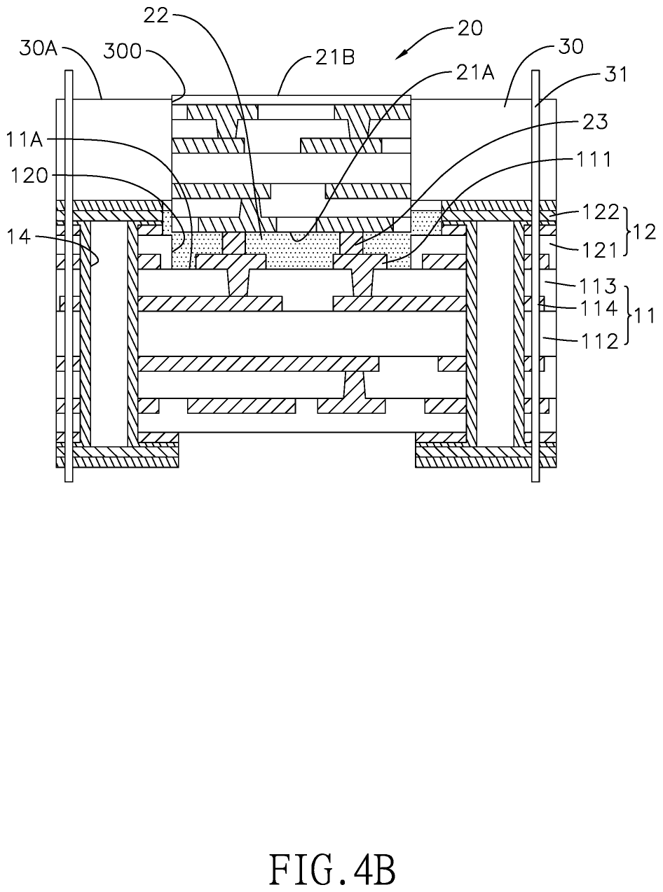

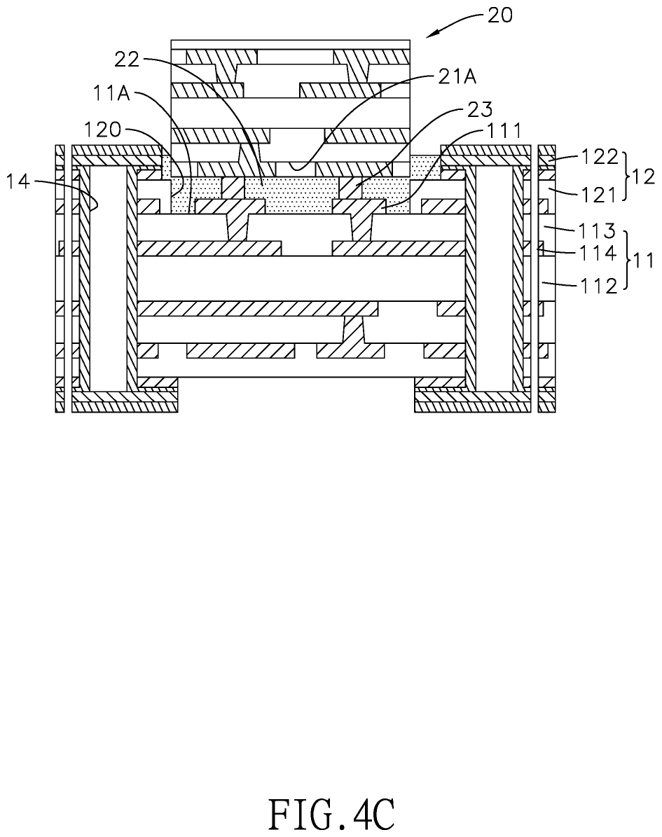

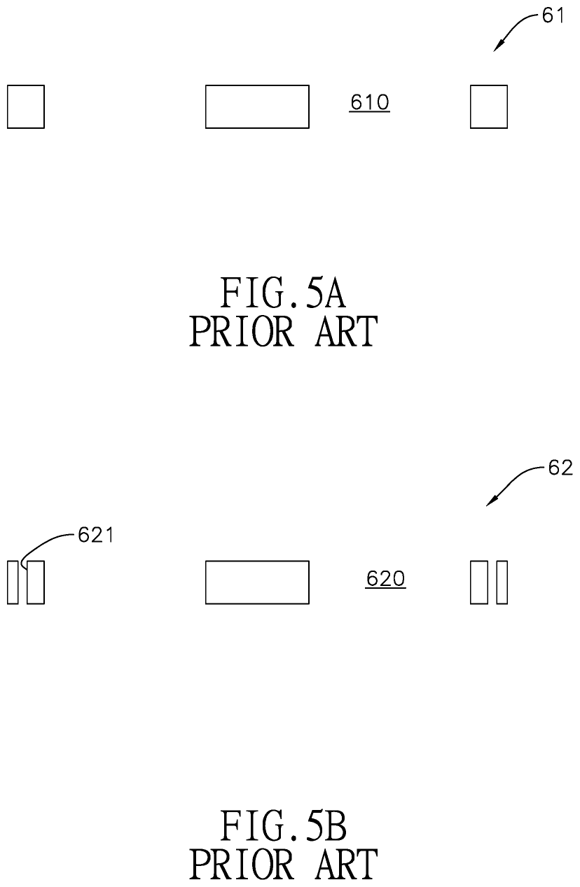

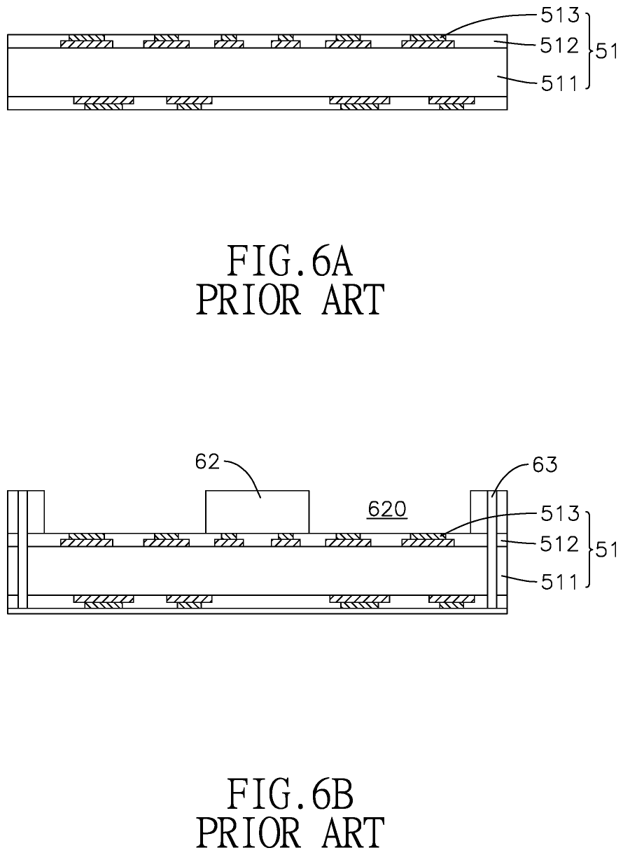

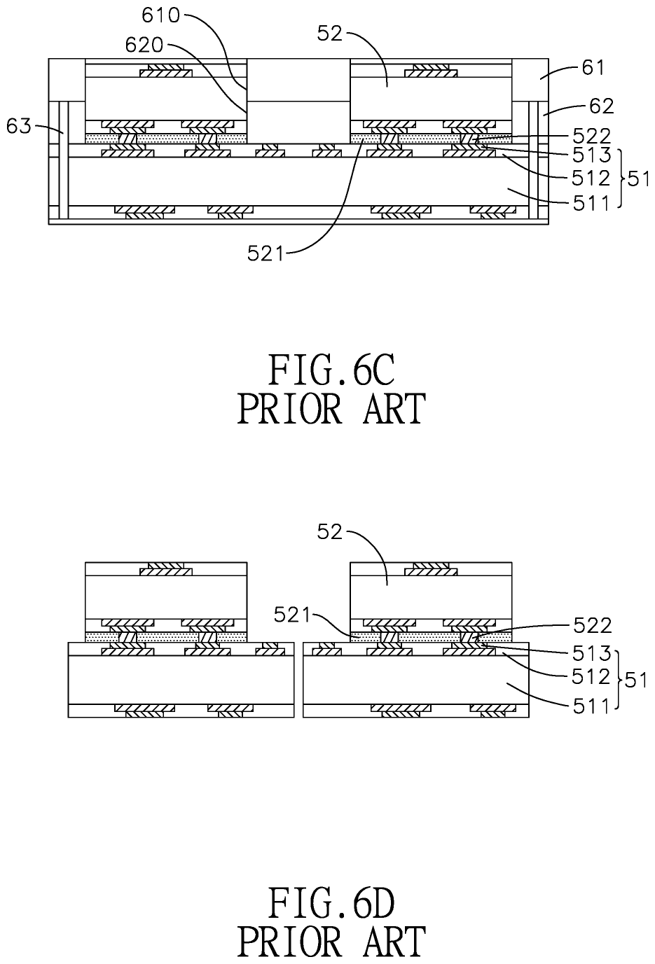

With reference to FIG. 4A, the docking surface 21A of the second circuit board 20 faces the docking opening 120 of the first circuit board 10, and this step is to place the second circuit board 20 in the docking opening 120. When the second circuit board 20 falls into the docking opening 120, the second circuit board 20 fits in the docking opening 120 since the spatial shape of the docking opening 120 corresponds to the shape of the second circuit board, and the alignment for the second circuit board 20 is automatically done by the docking opening 120 of the first circuit board 10.

With reference to FIG. 4B, this step is to prepare a fixture 30 having an accommodation opening 300, and to mount the fixture 30 on the first build-up circuit structure 12 of the first circuit board 10 by rivet 31, such that the second circuit board 20 is accommodated in the accommodation opening 300. Preferable, the top surface 30A of the fixture 30 is slightly lower than a bottom surface 21B of the second circuit board 20 that is opposite to the docking surface 21A. For example, the top surface 30A of the fixture 30 may be lower for about 1 mm to 5 mm. Then, a next step is to exert a force on the top surface 30A of the fixture 30 and the bottom surface 21B of the second circuit board 20 to press the second circuit board 20 and the first circuit board 10, so that the adhesive layer 22 of the second circuit board 20 may be bonded to the first surface 11A of the inner circuit structure 11 in the docking opening 120, and the docking bump 23 of the second circuit board 20 is connected to the docking pad 111 of the first circuit board 10.

With reference to FIG. 4C, this step is to remove the fixture 30 and the rivet 31, and the circuit board module with a docking structure is accomplished.

It shall be noted that, in the present invention, the second circuit board 20 is aligned and fixed by the docking opening 120. The fixture 30 and its accommodation opening 300 only provide a protecting effect during the process of pressuring, to protect the second circuit board 20 from damage of sideway external force. Since the fixture 30 is not required for aligning purpose, the precision for mounting the rivet 31 does not affect the precision of the aligning of the second circuit board 20.

The second circuit board 20 is mounted in the docking opening 120 of the first build-up circuit structure 12 of the first circuit board 10, with the docking surface 21A facing the first surface 11A in the docking opening 120. The adhesive layer 21 is bonded to the first surface 11A and the docking bump 23 connected to the docking pad 111 of the inner circuit structure of the first circuit board 10. Therefore, the circuit layer 212 of the second circuit board 20 may be electrically connected to the circuit layer 114, the first circuit layer 122, or the second circuit layer 132 of the first circuit board 10.

In the conventional art, the rivet and the resin blocking layer are utilized to prevent overflowing of the adhesive layer and provide aligning and fixing functions for the second circuit board. The positioning of the resin blocking layer may not be precise enough and may cause dispositioning of the second circuit board. Compared to the conventional art, in the present invention, the docking opening 120 of the first circuit board 10 ensures the precision of the aligning of the second circuit board 20. Furthermore, after the pressuring and bonding of the first circuit board 10 and the second circuit board 20, the second circuit board 20 is still fixed in the docking opening 120, such that the bonding between the first and second circuit boards 10, 20 is assured in the following usages.

In conclusion, the first circuit board 10 and the circuit board module including the first circuit board 10 of the present invention provide the precise aligning effect for the second circuit board 20 with the forming of the docking opening 120 in the first build-up circuit structure 12. The docking opening 120 also accommodates the adhesive layer 24 of the second circuit board 20, to prevent the adhesive layer 24 from overflowing during pressuring. The docking opening 120 replaces the resin blocking layer as mentioned in the conventional art, and further addresses the problems including low positioning accuracy of using rivet for fixing, residue of the resin blocking layer, and high cost of the resin blocking layer.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A circuit board with a docking structure, comprising:
an inner circuit structure, having a first surface and a docking pad on the first surface; and
a first build-up circuit structure, mounted on the first surface of the inner circuit structure, and having a docking opening, wherein the docking pad is exposed in the docking opening.

2. The circuit board with a docking structure as claimed in claim 1, wherein a spatial shape of the docking opening of the first build-up circuit structure fits a shape of a circuit board to be docked.

3. The circuit board with a docking structure as claimed in claim 1, wherein the first build-up circuit structure comprises:
a first dielectric layer, mounted on the first surface of the inner circuit structure, and having the docking opening; and
a first circuit layer, mounted on the first dielectric layer, and having a circuit pattern that does not cover the docking opening.

4. The circuit board with a docking structure as claimed in claim 1, further comprising:
a second build-up circuit structure, mounted on a second surface of the inner circuit structure, and including a second circuit structure, wherein the second surface of the inner circuit structure is opposite to the first surface of the inner circuit structure; and
a conducting via, comprising:
a through hole, formed through the first build-up circuit structure, the inner circuit structure, and the second build-up circuit structure;
a conductive layer, mounted on an inner wall of the through hole, and electrically connected to the first circuit layer of the first build-up circuit structure and the second circuit layer of the second build-up circuit structure; and
a hole filler, filled in the through hole.

5. A circuit board module with a docking structure, comprising:
a first circuit board, comprising:
an inner circuit structure, having a first surface and a docking pad on the first surface; and
a first build-up circuit structure, mounted on the first surface of the inner circuit structure, and having a docking opening, wherein the docking pad is exposed in the docking opening; and
a second circuit board, having a docking surface, and comprising:
an adhesive layer, mounted on the docking surface; and
a docking bump, mounted on the docking surface and protruding from the adhesive layer; wherein
the second circuit board is mounted in the docking opening of the first circuit board, the docking surface of the second circuit board faces the first surface in the docking opening, the docking bump is connected to the docking pad of the inner circuit structure, and the adhesive layer adheres to the first surface.

6. The circuit board module with a docking structure as claimed in claim 5, wherein
a spatial shape of the docking opening of the first build-up circuit structure of the first circuit board fits a shape of the second circuit board.

7. The circuit board module with a docking structure as claimed in claim 5, wherein the first build-up circuit structure of the first circuit board comprises:
a first dielectric layer, mounted on the first surface of the inner circuit structure, and having the docking opening; and
a first circuit layer, mounted on the first dielectric layer, and having a circuit pattern that does not cover the docking opening.

8. The circuit board module with a docking structure as claimed in claim 7, wherein the first circuit board comprises:
a second build-up circuit structure, mounted on a second surface of the inner circuit structure, and including a second circuit structure, wherein the second surface of the inner circuit structure is opposite to the first surface of the inner circuit structure; and
a conducting via, comprising:
a through hole, formed through the first build-up circuit structure, the inner circuit structure, and the second build-up circuit structure;
a conductive layer, mounted on an inner wall of the through hole, and electrically connected to the first circuit layer of the first build-up circuit structure and the second circuit layer of the second build-up circuit structure; and
a hole filler, filled in the through hole.

9. A manufacture method of a circuit board with a docking structure, comprising steps of:
preparing an inner circuit structure having a first surface and a docking pad on the first surface;
mounting a release film on the first surface, wherein the release film covers the docking pad;
mounting a first build-up circuit structure on the first surface of the inner circuit structure;
forming a groove along an edge of the release film on a surface of the first build-up circuit structure, wherein the groove is formed through the first build-up circuit structure toward a surface of the inner circuit structure, such that a part of the first build-up circuit structure on top of the release film is separated from the rest of the first build-up circuit structure; and
removing the release film from the first surface of the inner circuit structure to remove the part of the first build-up circuit structure on top of the release film and expose the docking pad, to form a docking opening in the first build-up circuit structure.

10. The manufacture method of a circuit board with a docking structure as claimed in claim 9, wherein
a spatial shape of the docking opening of the first build-up circuit structure fits a shape of a circuit board to be docked.

11. The manufacture method of a circuit board with a docking structure as claimed in claim 9, further comprising steps of:
mounting a second build-up circuit structure on a second surface of the inner circuit structure; wherein the second surface of the inner circuit structure is opposite to the first surface of the inner circuit structure; wherein the step of mounting the first build-up circuit structure or mounting the second build-up circuit structure further comprises sub-steps of:
mounting a first dielectric layer covering the first surface of the inner circuit structure, and mounting a second dielectric layer covering the second surface of the inner circuit structure; and
mounting a first circuit layer on a surface of the first dielectric layer, and mounting a second circuit layer on a surface of the second dielectric layer; wherein the first circuit layer has a circuit pattern that does not cover a region above the release film.

12. The manufacture method of a circuit board with a docking structure as claimed in claim 11, wherein after mounting the first dielectric layer and the second dielectric layer, the manufacture method further comprises sub-steps of:
performing a drilling process to form a through hole through the inner circuit structure, the first dielectric layer, and the second dielectric layer;
performing an electroplating process to form a conductive layer in the through hole and on the surface of the first dielectric layer and the surface of the second dielectric layer, and filling the through hole with a hole filler, to form a conducting via; wherein
the first circuit layer is mounted on the conductive layer upon the first dielectric layer, and the second circuit layer is mounted on the conductive layer upon the second dielectric layer.

13. The manufacture method of a circuit board with a docking structure as claimed in claim 12, wherein after filling the through hole with the hole filler, the manufacture method further comprises steps of:
grinding the surface of the first dielectric layer and the surface of the second dielectric layer to remove redundant hole filler and reducing a thickness of the conductive layer on the first dielectric layer and the second dielectric layer;
mounting circuit metal layers on the conductive layer on the first dielectric layer and the second dielectric layer respectively; and
patterning the circuit metal layers on the first dielectric layer and the second dielectric layer to form the first circuit layer and the second circuit layer.
